(19) United States
(12) Patent Application Publication
(10) Pub. No.: US 2014/0167146 A1
(43) Pub. Date: Jun. 19, 2014

(54) TUNNELING FIELD EFFECT TRANSISTOR AND FABRICATION METHOD THEREOF

(71) Applicant: KYUNGPOOK NATIONAL UNIVERSITY INDUSTRY-ACADEMIC COOPERATION FOUNDATION, Daegu (KR)

(72) Inventors: In-man KANG, Daegu (KR); Jae-sung LEE, Daegu (KR)

(73) Assignee: KYUNGPOOK NATIONAL UNIVERSITY INDUSTRY-ACADEMIC COOPERATION FOUNDATION, Daegu (KR)

(21) Appl. No.: 14/086,457

(22) Filed: Nov. 21, 2013

(30) Foreign Application Priority Data
Dec. 17, 2012 (KR) 10-2012-0147583

(51) Int. Cl. H01L 29/78; H01L 29/66

(52) U.S. Cl. CPC H01L 29/7827; H01L 29/66666
USPC 257/329; 438/268

(57) ABSTRACT

A tunneling field effect transistor (FET) and a method of fabricating the same are provided. The tunneling FET includes a first electrode formed on a substrate, a second electrode disposed over the first electrode with respect to the substrate, a channel layer which connects the first electrode and the second electrode, and a plurality of third electrodes formed on sidewalls of the channel layer, wherein the channel layer is higher than the third electrodes in the criteria of the substrate.

### CROSS-REFERENCE TO RELATED APPLICATION

This application claims priority from Korean Patent Application No. 10-2012-0147583, filed on Dec. 17, 2012, in the Korean Intellectual Property Office, the disclosure of which is incorporated herein by reference in its entirety.

### BACKGROUND

1. Field

Apparatuses and methods consistent with exemplary embodiments relate to a tunneling field effect transistor (FET) and a method of fabricating the same, and more particularly, to a vertical tunneling FET having dual gate electrodes capable of increasing an operation current through formation of double electron-hole layers and further increasing the operation current with maintenance of a fixed cross-sectional area, and a method of fabricating the same.

2. Description of the Related Art

The concept of tunneling FETs was first suggested in Hitachi, Ltd. of Japan and Cambridge University of the United Kingdom. In 1990s, since miniaturization of existing MOSFETs had been smoothly made and an issue for energy was not in a serious situation, the tunneling FETs had not been widely studied. However, at the turn of 2000s, a limitation for the miniaturization of the MOSFETs is imminent and the issue for energy is in a serious situation. As one of solutions, the studies on the tunneling FETs come into the spotlight again. This is because the need for development of the devices which replace or supplement the existing MOSFETs is on the rise with increase in power consumption as the counterbalance of reduction in a size of the semiconductor device and improvement of performance.

In general tunneling FETs, most tunneling is generated in a junction surface between a source and a channel and a surface close to a gate insulating layer and the tunneling is generated to a horizontal direction from the source toward the channel. Thus, an amount of charges contributing to the tunneling is too small and the actual operation current is low.

Therefore, to improve the operation current of the tunneling FET, an area of a region in which the tunneling is generated has to be increased. To increase the tunneling region in the related art, a cross-sectional area in a wafer, which is occupied by the device, is inevitably increased and thus it is difficult to increase the operation current through the increase of the cross-sectional area in the wafer. For example, when the cross-sectional area in the wafer is increased, the number of device produced per a wafer is reduced and thus a fabrication cost is increased.

### SUMMARY

One or more exemplary embodiments may overcome the above disadvantages and other disadvantages not described above. However, it is understood that one or more exemplary embodiment are not required to overcome the disadvantages described above, and may not overcome any of the problems described above.

One or more exemplary embodiments are to provide a vertical tunneling FET having dual gate electrodes capable of increasing an operation current through formation of double electron-hole layers and further increasing the operation current with maintenance of a fixed cross-sectional area, and a method of fabricating the same.

According to an aspect of an exemplary embodiment, there is provided a tunneling field effect transistor (FET). The tunneling FET may include: a first electrode formed on a substrate; a second electrode disposed over the first electrode with respect to the substrate; a channel layer configured to connect the first electrode and the second electrode; and a plurality of third electrodes formed on sidewalls of the channel layer. The channel layer may be formed so that a top of the channel layer is higher than those of the third electrodes with respect to the substrate.

The tunneling FET may further include an insulating layer configured to insulate the plurality of third electrodes from the first electrode, the channel layer, and the second electrode.

The plurality of third electrodes may receive voltages having different polarities from each other.

The first electrode may be doped with a high concentration P⁺ type impurity, the channel layer may be doped with a low concentration P⁻ type impurity, and the second electrode may be doped with a high concentration N⁺ type impurity.

The plurality of third electrodes may be formed to face each other in the channel layer and have a double gate structure.

The first electrode, the channel layer, and the second electrode may have a vertical structure with respect to the substrate.

According to another aspect of an exemplary embodiment, there is provided a method of fabricating a tunneling field effect transistor (FET). The method may include: forming a first electrode on a substrate; forming a second electrode over the first electrode with respect to the substrate; forming a channel layer configured to connect the first electrode and the second electrode; and forming a plurality of third electrodes on sidewalls of the channel layer. The forming a channel layer may include forming the channel layer so that a top of the channel layer is higher than those of the third electrodes with respect to the substrate.

The method may further include forming an insulating layer configured to insulate the plurality of third electrodes from the first electrode, the channel layer, and the second electrode.

The forming a plurality of third electrodes may include forming the plurality of third electrodes receiving voltages having different polarities from each other.

The first electrode may be doped with a high concentration P⁺ type impurity, the channel layer may be doped with a low concentration P⁻ type impurity, and the second electrode may be doped with a high concentration N⁺ type impurity.

The forming a plurality of third electrodes may include forming the plurality of third electrodes to face each other in the channel layer so that the third electrodes have a double gate structure.

The first electrode, the channel layer, and the second electrode may have a vertical structure with respect to the substrate.

According to the above-described various exemplary embodiments, since tunneling is generated in a horizontal direction as well as in the vertical direction, an area of a region in which the tunneling is generated is increased and thus an operation current may be increased.

According to the above-described various exemplary embodiments, since a gate formed along a channel is spaced from a drain region, leakage current due to an ambipolar behavior in the drain region is suppressed and thus high switching speed together with good subthreshold swing may be implemented.

Additional aspects and advantages of the exemplary embodiments will be set forth in the detailed description, will be obvious from the detailed description, or may be learned by practicing the exemplary embodiments.

### BRIEF DESCRIPTION OF THE DRAWING FIGURES

The above and/or other aspects will be more apparent by describing in detail exemplary embodiments, with reference to the accompanying drawings, in which:

FIG. 1 is a view illustrating a structure of a tunneling field effect transistor (FET) according to an exemplary embodiment;

FIG. 2 is a view illustrating a structure of a tunneling FET according to another exemplary embodiment;

FIG. 3 is a simulation diagram showing an electron-hole concentration profile of the tunneling FET of FIG. 1;

FIG. 4 is a view explaining current (I)-voltage (V) transfer characteristic of the tunneling FET of FIG. 1; and

FIGS. 5 to 9 are views illustrating a method of fabricating a tunneling FET according to an exemplary embodiment.

### DETAILED DESCRIPTION OF THE EXEMPLARY EMBODIMENTS

Hereinafter, exemplary embodiments will be described in more detail with reference to the accompanying drawings.

In the following description, same reference numerals are used for the same elements when they are depicted in different drawings. The matters defined in the description, such as detailed construction and elements, are provided to assist in a comprehensive understanding of the exemplary embodiments. Thus, it is apparent that the exemplary embodiments can be carried out without those specifically defined matters. Also, functions or elements known in the related art are not described in detail since they would obscure the exemplary embodiments with unnecessary detail.

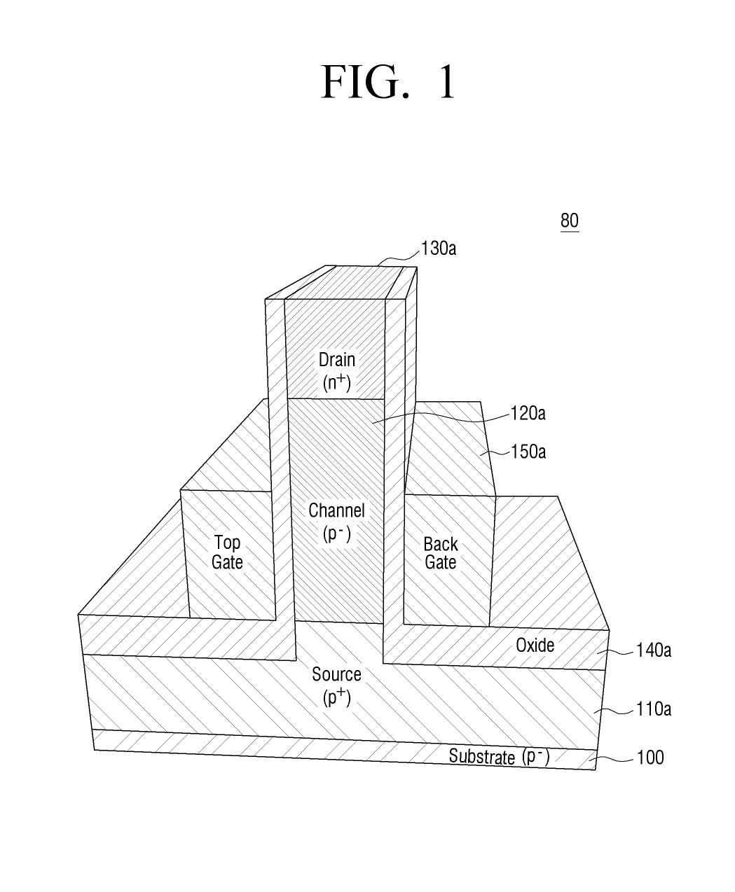

FIG. 1 is a view illustrating a structure of a tunneling field effect transistor according to an exemplary embodiment.

As illustrated in FIG. 1, a tunneling field effect transistor (hereinafter, referred to as a tunneling FET) 80 according to an exemplary embodiment partially or wholly includes a substrate 100, a first electrode 110a, a channel layer 120a, a second electrode 130a, an insulating layer 140a, and third electrodes 150a.

Here, the phrase “partially or wholly includes” may means that the tunneling FET may be configured that some components such as the insulating layer 140a are omitted or that some components such as the first electrode 110a are included in the substrate 100 and to fully understand the inventive concept, the tunnel FET may be interpreted to wholly include the components.

The substrate 100 may include any one of a wafer, a quartz substrate, and a glass substrate. In the exemplary embodiment, the substrate 100 may include a wafer in terms of a fabrication process of the semiconductor device. Here, the substrate 100 may be a low concentration P-doped wafer.

The first electrode 110a is formed on the substrate 100. The first electrode 110a may serve as, for example, a source in the tunneling FET 80. In an exemplary embodiment, the first electrode 100a may be doped with a high concentration P type impurity and a step for forming the second electrode 130a and a vertical transistor may be formed in a central region of the substrate 100. Here, the step has a stepwise shape and the step means that the central region is formed to be higher than or lower than a peripheral region of the substrate. The first electrode 110a may be formed by depositing a conductive material on the substrate 100 and patterning the conductive material through a photolithography process.

The channel layer 120a is formed on the first electrode 110a having the step in the central portion of the substrate 100. The channel layer 120a is doped with a low concentration P type impurity. The channel layer 120a is a kind of current path configured to flow current between the first electrode 110a serving as a source and the second electrode 130a serving as a drain.

The second electrode 130a is formed on the channel layer 120a. Through the formation of the second electrode 130a, the first electrode 110a, the channel layer 120a, and the second electrode 130a forms a vertical structure with respect to the substrate 100. Here, the second electrode 130a is doped with a high concentration N type impurity.

The insulating layer 140a is formed along a top of the first electrode 110a externally exposed, the step portion of the first electrode 110a forming the vertical structure when viewed in FIG. 1, and sidewalls of the channel layer 120a and the second electrode 130a. For example, the insulating layer 140a may be formed by forming an insulating layer including an oxide material and performing a photolithography process on the insulating layer after the second electrode 130a is formed. In the process of forming the insulating layer 140a, a top of the second electrode 130a may be externally exposed.

A plurality of third electrodes 150a are formed on the sidewall of the channel layer 120a. In an exemplary embodiment, the plurality of third electrodes 150a may be formed to face each other on both sidewalls of the channel layer 120a to form a double gate structure. The third electrodes 150a are gate electrodes and are doped with a high concentration N type impurity. In an exemplary embodiment, the plurality of third electrodes 150a formed at both sides of the channel layer 120a receive voltages having different polarities from each other. Here, for example, the phrase “receive voltages having different polarities from each other” may mean that the third electrodes 150a separately formed from each other may be respectively connected to a power supply unit configured to provide voltages having different polarities from each other. Alternatively, the phrase may mean that corresponding voltages may be provided to the third electrodes from a module used in the tunneling FET 80 under control of a controller.

For example, when a positive (+) voltage is applied to a third electrode (hereinafter, referred to as a top gate) 150a disposed at one side of the channel layer 120a and a negative (−) voltage is applied to a third electrode 150a (hereinafter, referred to as a back gate) disposed at the other side of the channel layer 120a, an inversion layer is formed to be gradually expanded in the channel layer 120a by an electric field of the gates. As a result, double layers by electrodes and holes are formed in the low concentration impurity-doped channel region by the positive (+) polarity and the negative (−) polarity of the gates. The double electron-hole layers may be seemed like a structure that a PN junction is formed by a P type layer and an N type layer. Therefore, the tunneling is generated to a direction perpendicular to the channel between the double electron-hole layers. At this time, the total operation current in the device is represented as a sum of a current by the tunneling between the source and the channel to a horizontal direction and a current by the tunneling in the double electron-hole layers of the channel to a vertical direction.

The tunneling FET 80 according to the exemplary embodiment may obtain a high operation current. Further, the tunneling FET 80 implements high concentration double electron-hole layers to reduce subthreshold swing (S) affecting the switching speed. That is, the switching speed may be adjusted.

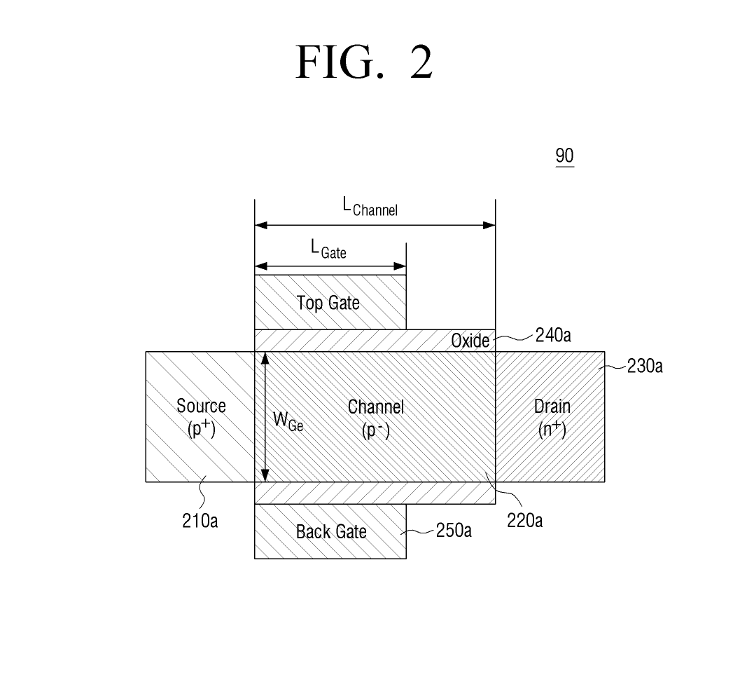

FIG. 2 is a view illustrating a structure of a tunneling FET according to another exemplary embodiment.

As illustrated in FIG. 2, a tunneling FET 90 according to another exemplary embodiment partially or wholly includes a substrate (not shown), a first electrode 210a, a channel layer 220a, a second electrode 230a, an insulating layer 240a, and a third electrode 250a. The phrase “partially or wholly includes” has the same meaning as described above.

As compared with FIG. 1, the tunneling FET 90 of FIG. 2 may increase an operation current through adjustment of a length of a channel in which the tunneling is generated in the vertical direction without increase in a cross-section area occupied by the device in the wafer.

In other words, the tunneling FET 80 of FIG. 1 may improve the operation current by increasing an area of a tunneling generating region through the tunneling generated in the vertical direction as well as in the horizontal direction. The tunneling FET 90 of FIG. 2 may implement good subthreshold swing (S) together with high switching speed by disposing the gate which is formed along the channel layer 220a to reduce band-bending in a channel-drain junction surface by a gate electric field, that is, the gate electrode 250a away from the drain region and suppressing leakage current due to an ambipolar behavior in the drain region of an off state.

The method according to an embodiment of the inventive concept may be applied to well-known existing methods for improving the operation current of the tunneling FET. Here, as the existing methods for solving the low operation current, there are a method of using a material having a low band gap material as a body, a method of increasing a gate electric field affecting a channel, a method of reducing a width of a tunneling barrier between a source and a channel, and the like.

Other than the above-described difference, the substrate (not shown), the first electrode 210a, the channel layer 220a, the second electrode 230a, the insulating layer 240a, and the third electrodes 250a of FIG. 2 may be substantially the same as the substrate 100, the first electrode 110a, the channel layer 120a, the second electrode 130a, the insulating layer 140a, and the third electrode 150a, and thus detailed description thereof will be omitted.

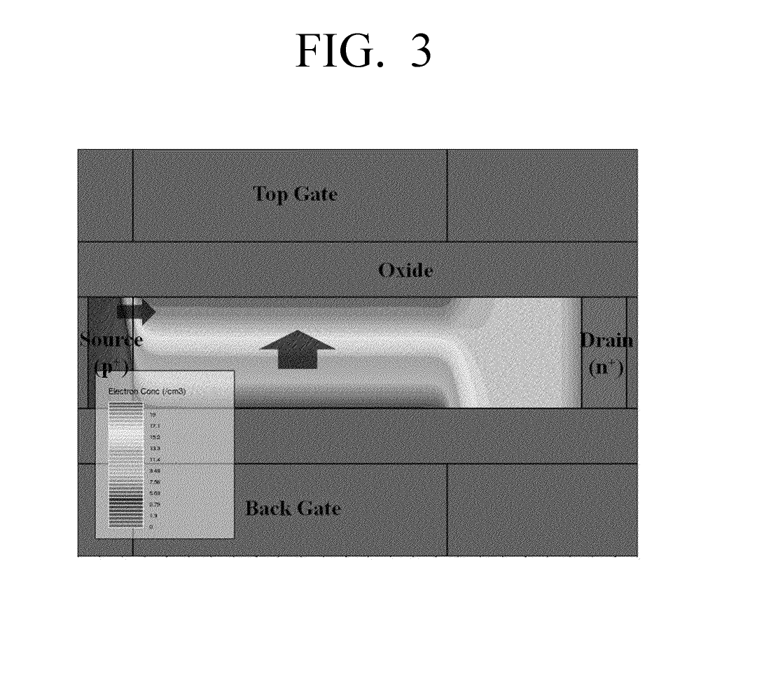

FIG. 3 is a simulation diagram illustrating an electron-hole concentration profile of the tunneling FET of FIG. 1.

The simulation was performed on the tunneling FETS 80 and 90 having the structures of FIGS. 1 and 2 according to the exemplary embodiments. In the device used for the simulation, germanium (Ge) was used for a body, the P type source was doped with a P type impurity having a concentration of 10²⁰/cm⁻⁶, the N type drain was doped with an N type impurity having a concentration of 10²⁰/cm⁻⁶, and the P type channel layer was doped with a P type impurity having a concentration of 10⁻¹⁵/cm⁻⁶. A length of the channel was 200 nm, a length of the gate was 140 nm, and a width of the channel was 6 nm.

It can be seen from FIG. 2 that when V_{TG}=V_{DS}=1 V and V_{BG}=−1 V, electrons and holes are intensively distributed in portions of the channel close to the top gate and the back gate, respectively and concentrations of the electrons and holes are about 10⁻²⁰/cm⁻⁶ larger than the concentration (10⁻¹⁵/cm⁻⁶) of the channel. It can be seen that the electron-hole distribution causes tunneling to be generated to a direction indicated by arrows and contributes to the operation current of the device.

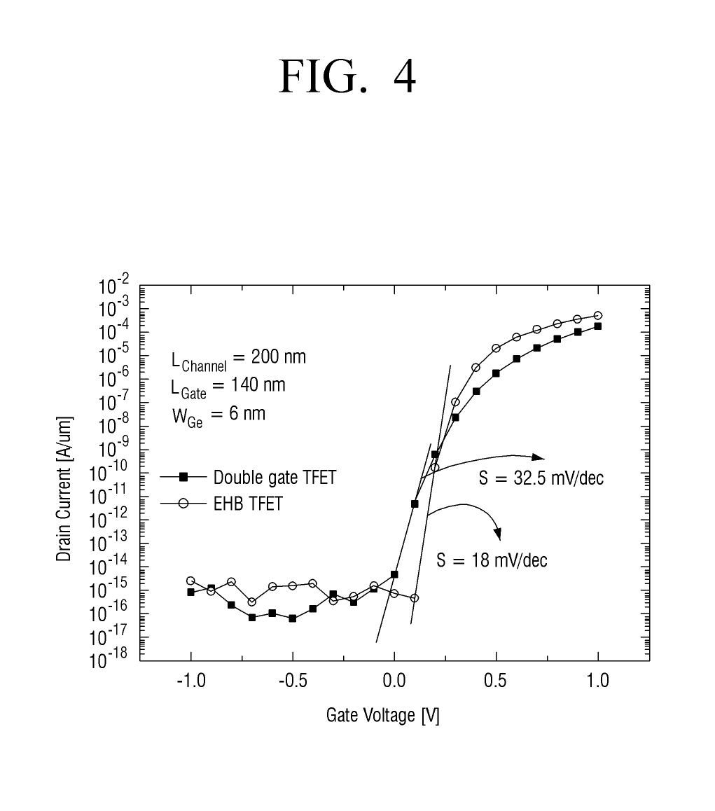

FIG. 4 is a view explaining current (I)-voltage (V) transfer characteristic of the tunneling FET of FIG. 1.

In FIG. 4, with respect to the vertical tunneling FETs having the same size, the I-V transfer characteristics are compared based on the simulation result for a double gate structure in which the positive (+) bias voltage is applied to the gates and a structure having the double electron-hole layers, in which the positive (+) bias voltage and the negative (−) bias voltage are respectively applied to the top gate and the back gate.

In the structure suggested in the exemplary embodiment, the drain current when V_{TG}=V_{DS}=1 V and V_{BG}=−1 V is about 500 μA/μm. The drain current is improved about 2.8 times as compared with the double gate structure having the drain current of 177 μA/μm, and the subthreshold swing (S) is 18 mV/dec and is about 1.8 times superior to the double gate structure having the subthreshold swing (S) of 32.5 mV/dec.

It can be seen from the above-described simulation results that the vertical tunneling FETs 80 and 90 having the double electron-hole layers according to the exemplary embodiments have the superior current characteristics through the tunneling in the vertical direction as well as in the horizontal direction as compared with the tunneling FET with the double gate structure having the same size as the tunneling FETs 80 and 90. The structure may be good solution for the low operation current which has been pointed out as a disadvantage of the existing tunneling FET.

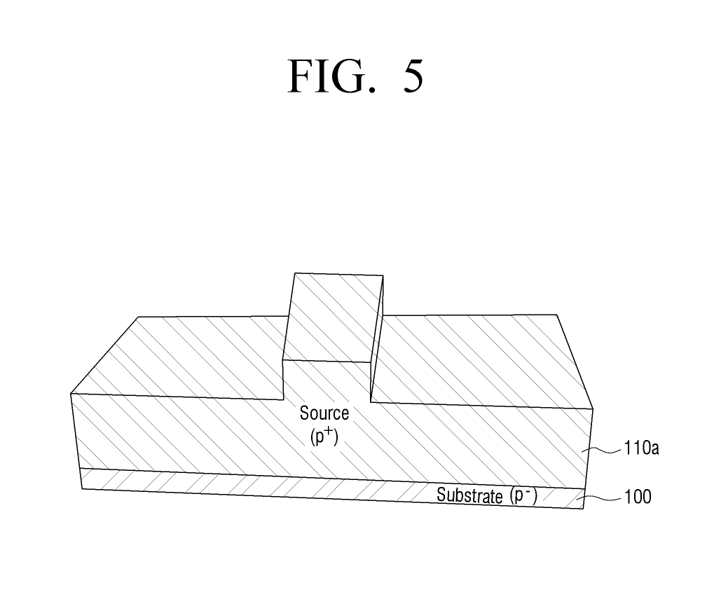

FIGS. 5 to 9 are views illustrating a method of fabricating a tunneling FET according to an exemplary embodiment.

For clarity, referring to FIGS. 5 to 9 together with FIG. 1, the method of fabricating a tunneling FET according to an exemplary embodiment includes preparing a substrate 100 doped with a low concentration P type impurity. Here, the substrate 100 may be a wafer on which the low concentration P type doping process is performed. Alternatively, the substrate 100 may include a quartz substrate or a glass substrate other than the wafer.

Subsequently, as illustrated in FIG. 5, a first electrode 110a is formed on the substrate 100. At this time, the first electrode 110a has a step in a central region thereof. Specifically, the first electrode 110a may be formed to have the step in which the central region of the first electrode 110a is higher than a peripheral region thereof. The first electrode 110a may be formed by depositing a conductive material on the substrate 100, coating a photoresist (PR), exposing and developing the photoresist using a mask, and etching the conductive material. At this time, the step may be formed by performing an etch process on the conductive material to different depths in the central and peripheral regions according to the exposing degree such as full or half exposing. Since the first electrode 110a of the tunneling FET 80 according to an exemplary embodiment is doped with a high concentration P type impurity, after the depositing of the conductive material as described above, the doping of the P type impurity may be previously performed before the coating of the photoresist.

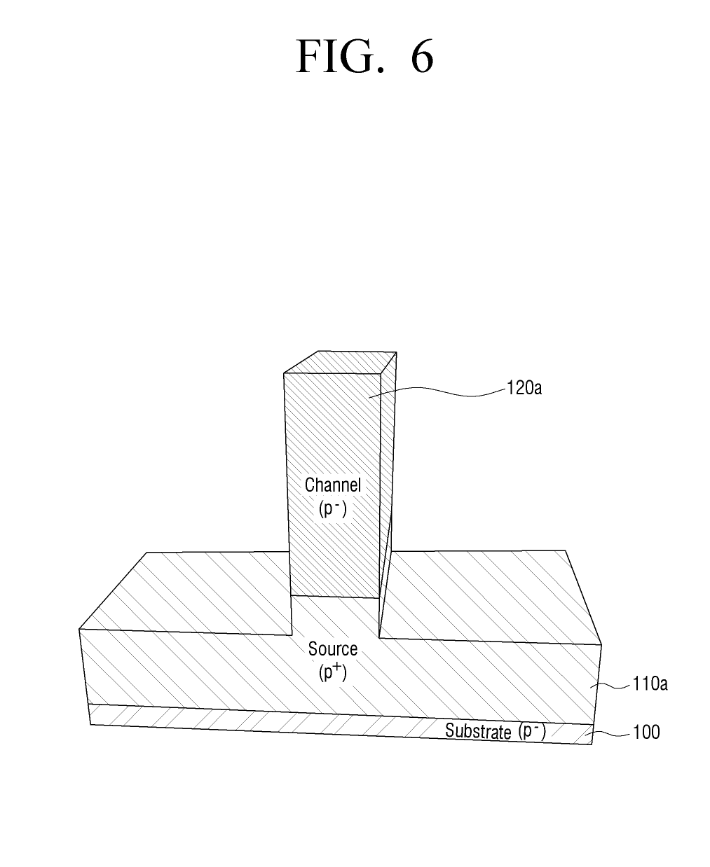

As illustrated in FIG. 6, a channel layer 120a is formed on the first electrode 110a. In order to form the channel layer 120a, more specifically, the channel layer 120a doped with a low concentration P type impurity, a process of forming the channel layer including depositing a material for the channel layer 120a on the substrate 100 on which the first electrode 110a is formed, doping the low concentration P type impurity, and performing a photolithography process and an etching process may be performed. Substantially, since the channel layer 120a may be formed by patterning the triple-layered layers after forming triple-layered layers, for example, an insulating layer, an amorphous silicon layer, and an N⁺ type deposition layer, the method of forming the channel layer 120a is not specifically limited thereto in an exemplary embodiment.

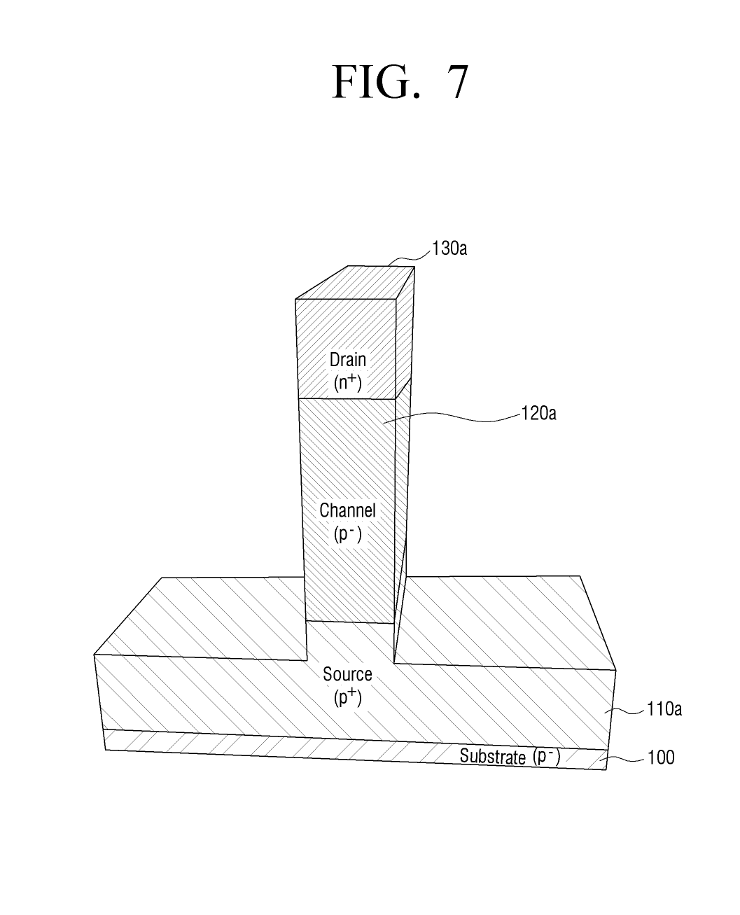

As illustrated in FIG. 7, a second electrode 130a is formed on the channel layer 120a. For example, a vertical structure of source-channel-drain in the tunneling FET 80 according to an exemplary embodiment may be formed through the forming of the second electrode 130a. Like the first electrode 110a, the second electrode 130a may be formed by depositing a conductive material on the substrate 100 including the channel layer 120a and then patterning the conductive material through a photolithography and an etching process. At this time, the second electrode 130a may be formed by depositing a conductive material and previously performing doping of a high concentration N type impurity before the patterning the conductive material through a photolithography and an etching process.

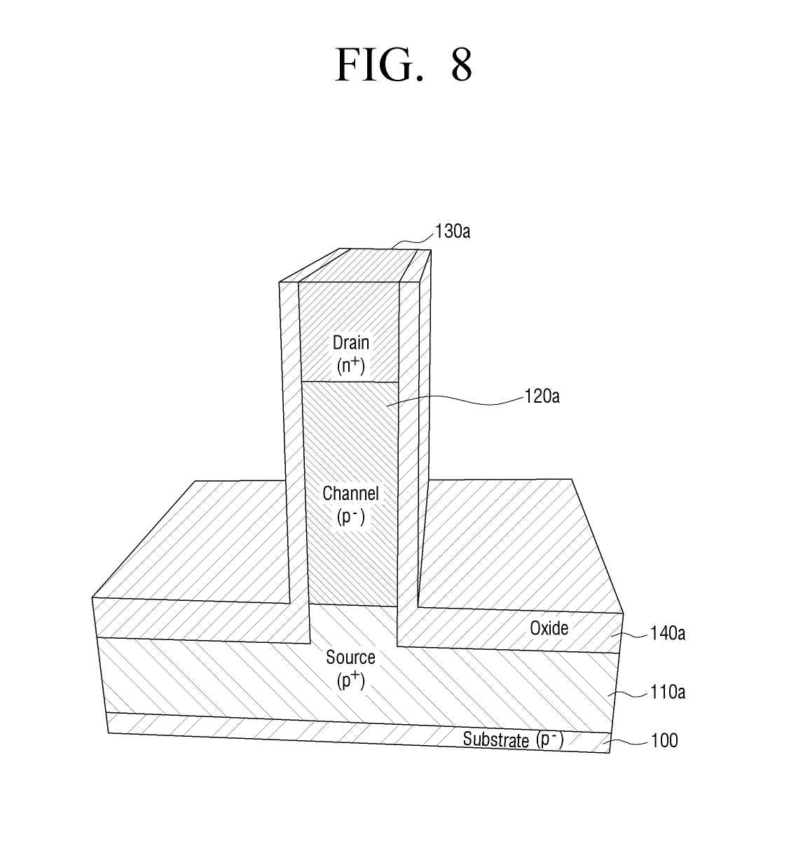

When the process of forming the second electrode 130a is completed, as illustrated in FIG. 8, an insulating layer 140a is formed on the semiconductor substrate 100. The insulating layer 140a may be formed by forming an insulating layer, for example, including an oxide material on the substrate 100 and performing a photolithography process to externally expose a portion of the second electrode 130a, that is, a top of the second electrode 130a. At this time, the insulating layer including the oxide material may be formed by any one method of an atmospheric pressure chemical vapor deposition (APCVD) method and a plasma enhanced CVD (PECVD) method.

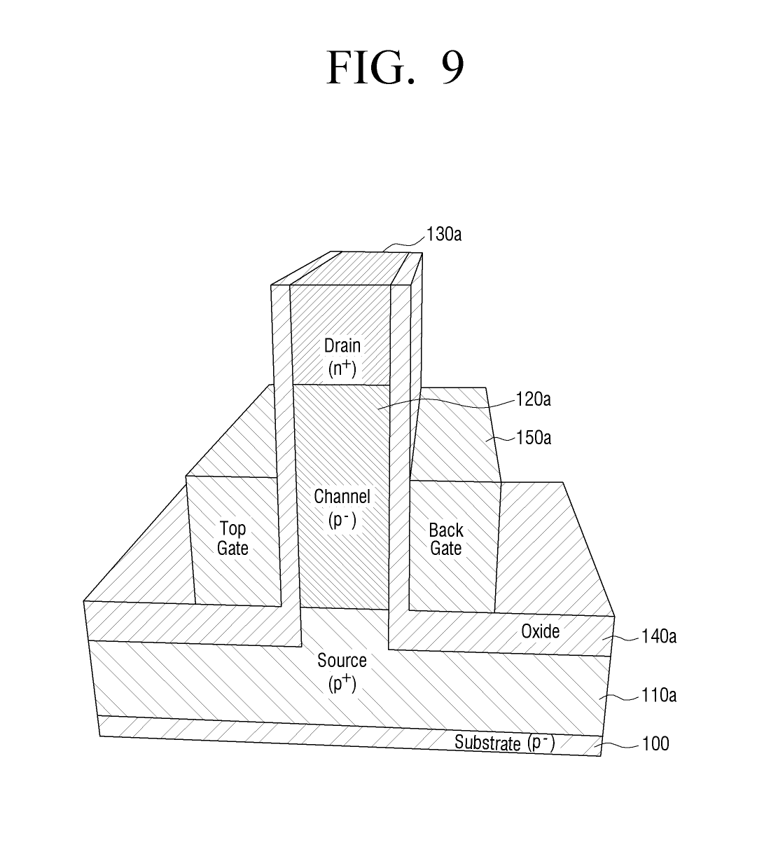

As illustrated in FIG. 9, a plurality of third electrodes 150a are formed. The plurality of third electrodes 150a are, for example, gates of the tunneling FET 80 and may be formed on both sidewalls of the channel layer 120a. More specifically, to form a double gate structure, the third gates 150a may be formed on the sidewalls of the channel layer 120a to face each other. In an exemplary embodiment, one of the third electrodes 150a disposed in the left of FIG. 9 may be referred to as a top gate and the other of the third electrodes 150a disposed in the right of FIG. 9 may be referred to as a back gate. Bias voltages having different polarities are applied to the top gate and the back gate, respectively. Here, the phrase “Bias voltages having different polarities are applied” may be interpreted to include a process of forming a pad or interconnection line to connect the gates with the power supply unit configured to provide respective voltages as described above.

The third electrodes 150a may be formed so that tops of the third electrodes are lower than a top of the channel layer 120a. For example, the third electrodes 150a may be disposed away from the second electrode 130a serving as the drain of the tunneling FET 80. Therefore, the tunneling FET 80 according to the exemplary embodiment may implement high switching speed as well as good S characteristic by suppressing leakage current due to the ambipolar behavior in the drain of an off state.

The exemplary embodiment has described that the third electrodes 150a are formed at the both sides of the channel layer 120a, but the third electrodes 150a are formed over three surfaces or four surfaces of the channel layer with the insulating layer 140a interposed therebetween in the tunneling FET 80 according to an exemplary embodiment so that the operation current of the tunneling FET 80 may be more increased. At this time, since voltages having different polarities from each other are applied to the third electrodes 150a formed on the three or four surfaces of the channel layer, the third electrodes 150a may be physically isolated from each other. For example, when the third electrodes are formed over the four surfaces of the channel layer, the third electrodes 150a over two surfaces and the third electrodes over the other two surfaces have to be formed to be physically isolated so that the voltages having electrically different polarities from each other are applied to the third electrodes 150a.

The foregoing exemplary embodiments and advantages are merely exemplary and are not to be construed as limiting the present inventive concept. The exemplary embodiments can be readily applied to other types of devices. Also, the description of the exemplary embodiments is intended to be illustrative, and not to limit the scope of the claims, and many alternatives, modifications, and variations will be apparent to those skilled in the art.

What is claimed is:

1. A tunneling field effect transistor (FET), comprising:
a first electrode formed on a substrate;
a second electrode disposed over the first electrode in the criteria of the substrate;
a channel layer which connects the first electrode and the second electrode; and
a plurality of third electrodes formed on sidewalls of the channel layer,
wherein the channel layer is higher than the third electrodes in the criteria of the substrate.

2. The tunneling FET as claimed in claim 1, further comprising an insulating layer configured to insulate the plurality of third electrodes from the first electrode, the channel layer, and the second electrode.

3. The tunneling FET as claimed in claim 1, wherein the plurality of third electrodes receive voltages having different polarities from each other.

4. The tunneling FET as claimed in claim 1, wherein the first electrode is doped with a high concentration P⁺ type impurity, the channel layer is doped with a low concentration P⁻ type impurity, and the second electrode is doped with a high concentration N⁺ type impurity.

5. The tunneling FET as claimed in claim 1, wherein the plurality of third electrodes are formed to face each other in the channel layer so that the third electrodes have a double gate structure.

6. The tunneling FET as claimed in claim 1, wherein the first electrode, the channel layer, and the second electrode have a vertical structure to the substrate.

7. A method of fabricating a tunneling field effect transistor (FET), the method comprising:
forming a first electrode on a substrate;
forming a second electrode over the first electrode in the criteria of the substrate;
forming a channel layer which connects the first electrode and the second electrode; and
forming a plurality of third electrodes on sidewalls of the channel layer,
wherein the forming a channel layer includes forming the channel layer which is higher than the third electrodes in the criteria of the substrate.

8. The method as claimed in claim 7, further comprising forming an insulating layer configured to insulate the plurality of third electrodes from the first electrode, the channel layer, and the second electrode.

9. The method as claimed in claim 7, wherein the plurality of third electrodes receive voltages having different polarities from each other.

10. The method as claimed in claim 7, wherein the first electrode is doped with a high concentration P⁺ type impurity, the channel layer is doped with a low concentration P⁻ type impurity, and the second electrode is doped with a high concentration N⁺ type impurity.

11. The method as claimed in claim 7, wherein the forming a plurality of third electrodes includes forming the plurality of third electrodes to face each other in the channel layer so that the third electrodes have a double gate structure.

12. The method as claimed in claim 7, wherein the first electrode, the channel layer, and the second electrode have a vertical structure with respect to the substrate.
